(19) United States
(12) Patent Application Publication
(10) Pub. No.: US 2001/0011741 A1
(43) Pub. Date: Aug. 9, 2001

(54) SEMICONDUCTOR MEMORY DEVICE AND MANUFACTURING METHOD THEREOF

(76) Inventor: TAKASHI URABE, TOKYO (JP)

Correspondence Address: MCDERMOTT WILL & EMERY, 600 13TH STREET, N.W., WASHINGTON, DC, 20005-3096, US

(21) Appl. No.: 09/123,455

(22) Filed: Jul. 28, 1998

(30) Foreign Application Priority Data
Jan. 8, 1998 (JP) 10-2372

(51) Int. Cl. H01L 27/108; H01L 29/76; H01L 29/94

(52) U.S. Cl. 257/306

(57) ABSTRACT

In a semiconductor memory device having a memory cell section and a peripheral circuit section, a cell plate is formed so as to be opposed to a storage node for charge storage of the memory cell by using a low-resistivity conductive layer. In the peripheral circuit section, a signal line is formed from the same low-resistivity conductive layer. As a result, a level difference between the memory cell section and the peripheral circuit section after the memory cell formation can be reduced.

### BACKGROUND OF THE INVENTION

1. Field of the Invention

The present invention relates to a semiconductor device and its manufacturing method intended for reduction of a chip size.

2. Background Art

FIG. 3 is a sectional view showing a structure of a main part of a DRAM as a conventional semiconductor memory device. In this type of stacked DRAM memory cell, the absolute value of the capacitance for storing a signal charge should not be reduced to cope with problems of software errors, even when the miniaturization proceeds.

As shown in FIG. 3, the DRAM has a memory cell section A and a peripheral circuit section B. An interlayer insulating film 5 is formed on a semiconductor substrate 7, and word lines 1 and bit lines 2 are arranged in the interlayer insulating film 5.

In the memory cell section A, a storage node 3 is formed so as to reach the semiconductor substrate 1 through the interlayer insulating film 5. Having a protrusion that protrudes from the interlayer insulating film 5, the storage node 3 constitutes a lower electrode for charge storage. A cell plate 4, which is formed on the protrusion with a thin insulating film 3′ interposed in between, constitutes an upper electrode for charge storage. An upper-layer interlayer insulating film 6 is formed in the memory cell section A and the peripheral circuit section B so as to cover the cell plate 4 and the entire interlayer insulating film 5.

In the above stacked DRAM memory cell, to secure a sufficiently large absolute value of the capacitance of the signal charge storage capacitor, the storage node (lower electrode) 3 for charge storage of the memory cell is given a shape that extends three-dimensionally in the height direction. As a result, as shown in FIG. 3, a large level difference 8′ exists between the memory cell section A and the peripheral circuit section B. Usually, since the head portion, i.e., the protrusion, of the storage node 3 and the cell plate 4 have thickness of about 0.6 μm and about 0.2 μm, respectively, the level difference 8′ (distance d′) amounts to about 0.8 μm.

Therefore, as shown in FIG. 4, if a mask 9 for photolithography is focused (indicated by reference numeral 10) on the part of the surface of the interlayer insulating film 6 in the memory cell section A, it is defocused (indicated by numeral 11′) in the peripheral circuit section B and its image is blurred there. For this reason, design rules to be applied to the peripheral circuit section B after the memory cell formation need to be relaxed. As a result, the peripheral circuit section B becomes relatively large, resulting in a large chip size.

Further, a conductive layer from which the cell plate 4 is formed has too large a resistivity to be used for forming a signal transmission line.

### SUMMARY OF THE INVENTION

The present invention has been made to solve the above problems in the conventional art, and therefore it is an object of the present invention to provide a semiconductor memory device and its manufacturing method which can reduce the level difference between the memory cell section after the memory cell formation and the peripheral circuit section, thereby enabling chip size reduction.

According to one aspect of the present invention, a semiconductor memory device has a memory cell section and a peripheral circuit section, and comprises a semiconductor substrate common to both the memory cell section and the peripheral circuit section. An interlayer insulating layer is disposed on the semiconductor substrate extending to both the memory cell section and the peripheral circuit section. A lower electrode for charge storage is provided on the interlayer insulating layer in the memory cell section. An upper electrode is provided so as to be opposed to the lower electrode in the memory cell section, and is composed of a low-resistivity conductive layer. A signal line is provided on the interlayer insulating layer in the peripheral circuit section, and is formed from the same low-resistivity conductive layer as the upper electrode in the memory cell section.

In the semiconductor memory device, the low-resistivity conductive layer is preferably formed of either silicide layer, a double layer structure of a polysilicon layer and a silicide layer, or a metal layer.

According to another aspect of the present invention, in a manufacturing method of a semiconductor memory device having a memory cell section and a peripheral circuit section, an interlayer insulating film is formed on a semiconductor substrate. An opening is formed in the interlayer insulating film in the memory cell section. A lower electrode for charge storage is formed to fill in the opening and to have a protrusion that protrudes from the interlayer insulating film. The protrusion of the lower electrode is covered with a thin insulating film. A low-resistivity conductive film is formed on the protrusion of the lower electrode that is covered with the thin insulating film and on the entire interlayer insulating film in the memory cell section and the peripheral circuit section. Further, an upper electrode for charge storage is formed to oppose to the lower electrode from the conductive layer in the memory cell section, and concurrently a signal line is formed from the conductive layer in the peripheral circuit section.

In the manufacturing method, the low-resistivity conductive layer is preferably formed by either a silicide layer, a double layer structure of a polysilicon layer and a silicide layer, or a metal layer.

Other and further objects, features and advantages of the invention will appear more fully from the following description.

### BRIEF DESCRIPTION OF THE DRAWINGS

FIG. 1 is a sectional view showing a structure of a DRAM as an example of a semiconductor memory device according to a first embodiment of the present invention.

FIG. 2 is a sectional view showing another structure of a DRAM as a semiconductor memory device according to a second embodiment of the present invention.

FIG. 3 is a sectional view showing a structure of a main part of a DRAM as a conventional semiconductor memory device.

FIG. 4 is a sectional view showing a focusing in a conventional semiconductor memory device.

### BEST MODE OF CARRYING OUT THE INVENTION

The preferred embodiments of the present invention will be hereinafter described with reference to the accompanying drawings. In the drawings, the same reference symbols represent the same or equivalent parts.

First Embodiment

FIG. 1 is a sectional view showing a structure of a DRAM as an example of a semiconductor memory device according to a first embodiment of the present invention.

In FIG. 1, A and B denote a memory cell section and a peripheral circuit section of the DRAM, respectively.

In this embodiment, a semiconductor substrate 7 is a silicon substrate. A lower interlayer insulating film 5 is formed on the semiconductor substrate 7, and an upper-layer interlayer insulating film 6 is formed on the interlayer insulating film 5. The interlayer insulating films 5 and 6 are composed of silicon oxide films.

Word lines 1 are formed in the interlayer insulating film 5 adjacent to the substrate 7 as a first conductive layer, and ais composed of silicide. Bit lines 2 are formed in the interlayer insulating film 5 from a second conductive layer positioned higher than the first conductive layers 1, and are composed of silicide.

A lower electrode 3 is formed as a third conductive layer, which is a polysilicon layer, and is formed so as to fill in an opening that is located between a pair of the word lines 1 and between a pair of the bit lines 2 and penetrates through the interlayer insulating film 5. Having an enlarged top portion, the lower electrode 3 works as a lower electrode for a memory capacitor, i.e., a storage node.

A thin insulating film 3′ is formed on the surface of the head portion, i.e., the enlarged portion, of the lower electrode 3 that protrudes from the first interlayer insulating film 5. An upper electrode 4 is formed as a fourth conductive layer, which is a silicide layer, and is formed so as to be opposed to the lower electrode 3 with the insulating film 3′ interposed in between. The upper electrode 4 is a metal silicide layer of WSi or the like, and hence has a low resistance. The upper electrode 4 works as an upper electrode for the memory capacitor, i.e., a cell plate.

In the peripheral circuit section B, a signal line layer 4a is formed on the interlayer insulating film 5. The signal line layer 4a is formed at the same time by using the same material (metal silicide such as WSi) as the silicide layer 4 in the memory cell section A, and hence has a low resistance.

A manufacturing process of the above DRAM will be described below. First, an interlayer insulating film 5 is formed on a semiconductor substrate 7. In the memory cell section A, an opening is formed in the interlayer insulating film 5, and a lower electrode 3 is formed to fill in the opening and to have a protrusion that protrudes from the interlayer insulating film 5 for charge storage. The protrusion of the lower electrode 3 is covered with a thin insulating film 3′. Then, a low-resistivity conductive layer is formed in the memory cell section A and in the peripheral circuit section B over the entire interlayer insulating film 5 and over the protrusion of the lower electrode 3 that is covered with the thin insulating film 3′. Thereafter, an upper electrode 4 for charge storage is formed from the conductive layer in the memory cell section A to be opposed to the lower electrode 3. Concurrently, a signal line 4a is formed from the same conductive layer in the peripheral circuit section B.

In this manner, the upper electrode 4 for charge storage in the memory cell section A and the signal line 4a in the peripheral circuit section B are formed from the same low-resistivity conductive layer that is formed over the entire interlayer insulating film 5 at one time.

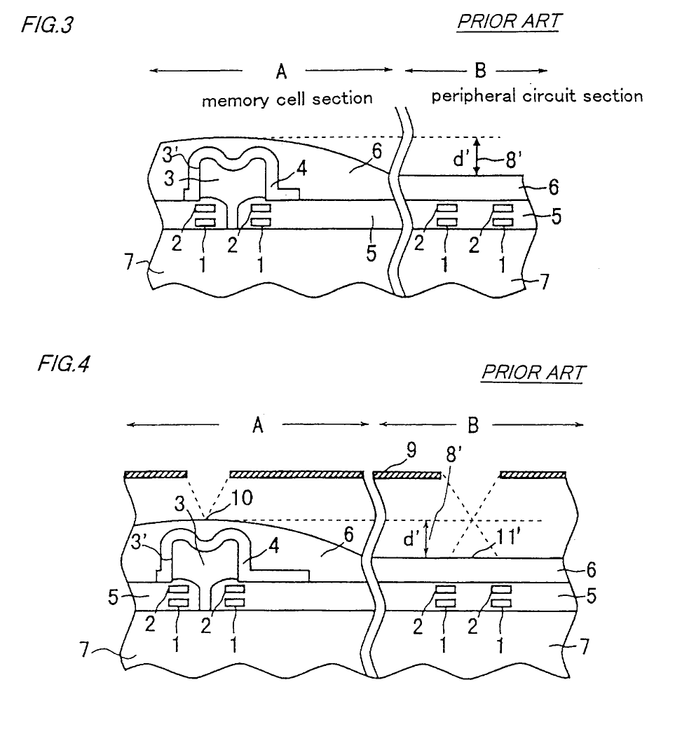

As shown in FIG. 1, in the DRAM having the above configuration, a level difference 8 (length d) between the surfaces of the interlayer insulating film 6 in the memory cell section A and in the peripheral circuit section B is smaller than the level difference 8′ (length d′) of the conventional DRAM shown in FIG. 3 by the height of the signal line layer 4a.

As shown in FIG. 1, if a mask 9 for photolithography is focused (indicated by reference numeral 10) on the part of the surface of the interlayer insulating film 6 in the memory cell section A, it is defocused (indicated by numeral 11) in the peripheral circuit section B. However, the degree of defocusing is reduced by an amount corresponding to the reduction in the distance between the plane of focus and the surface of the interlayer insulating film 6 in the peripheral circuit section B. Therefore, the design rules to be applied to the peripheral circuit section B after the memory cell formation are improved from those in the conventional case. As a result, chip size may be reduced, because the large peripheral circuit section B can be reduced.

In this embodiment, the cell plate in the memory cell section A and the signal line layer in the peripheral circuit section B are formed at the same time from the same low-resistivity conductive layer. As a result, the level difference between the memory cell section A and the peripheral circuit section B is reduced. The number of wiring layers are increased in the peripheral circuit section B, contributing to chip shrinking.

Second Embodiment

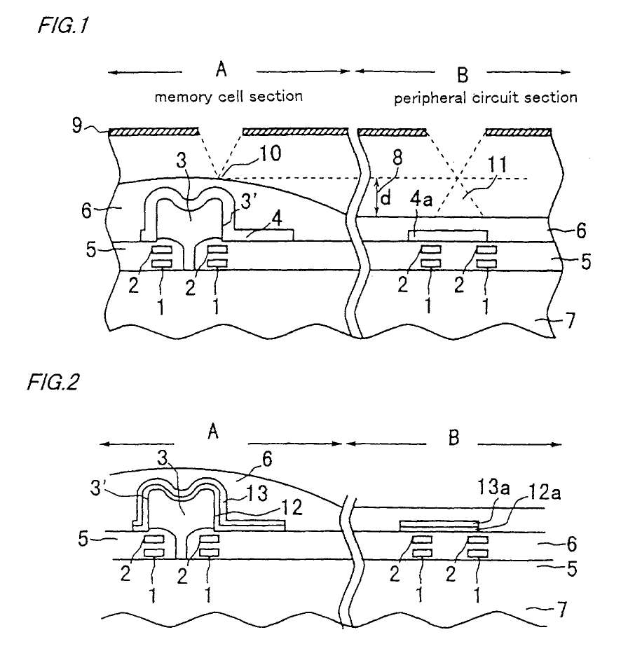

FIG. 2 is a sectional view showing a structure of a DRAM as a semiconductor memory device according to a second embodiment of the present invention.

In FIG. 2, a bottom layer 12 of an upper electrode is a bottom layer of a fourth conductive layer, and composed of a polysilicon layer doped with phosphorus and having a low resistance. A top layer 13 of an upper electrode top layer 13 is an upper layer of a fourth conductive layer, and is composed of a silicide layer of WSi or the like and has a low resistance.

That is, in this embodiment, the upper electrode of a two-layer structure that consists of the phosphorus-doped polysilicon layer and the silicide layer corresponds to the upper electrode 4 of the DRAM shown in FIG. 1.

In connection with the above, in the peripheral circuit section B, a signal line of a two-layer structure that consists of a phosphorus-doped polysilicon layer as a signal line bottom layer 12a and a silicide layer as a signal line top layer 13a is formed at the same time as the upper electrode in the memory sell section. In this manner, the cell plate 12 and 13 in the memory cell section A and the low-resistance signal line 12a and 13a in the peripheral circuit section B can be formed at the same time.

In the above embodiment, the silicide layer as the top layer 13 of the upper electrode and as the top layer 13a of the signal line may be replaced by a metal layer of W or the like. The resistance of the signal line in the peripheral circuit section B may be reduced in the same manner.

Also with the above structure, a level difference 8 between the surface of the portion of interlayer insulating film 6 in the memory cell section A and that in the peripheral circuit section B is smaller than the level difference 8′ of the conventional DRAM of FIG. 3 by the height of the signal line 12a and 13a.

Since the degree of defocusing in the peripheral circuit section B is lowered as much, the second embodiment is effective for chip size reduction like the first embodiment.

As described above, the present invention can provide a semiconductor memory device and its manufacturing method which can reduce the level difference between the memory cell section after the memory cell formation and the peripheral circuit section, thereby enabling chip size reduction.

It is further understood that the foregoing description is a preferred embodiment of the disclosed device and that various changes and modifications may be made in the invention without departing from the spirit and scope thereof.

What is claimed is:

1. A semiconductor memory device having a memory cell section and a peripheral circuit section, comprising:
a semiconductor substrate common to both said memory cell section and said peripheral circuit section;
an interlayer insulating layer disposed on said semiconductor substrate extending to both said memory cell section and said peripheral circuit section;
a lower electrode for charge storage provided on said interlayer insulating layer in said memory cell section;
an upper electrode provided so as to be opposed to said lower electrode in said memory cell section, said upper electrode being comprised of a low-resistivity conductive layer;
a signal line provided on said interlayer insulating layer in said peripheral circuit section, said signal line being formed from the same low-resistivity conductive layer as said upper electrode in said memory cell section.

2. The semiconductor memory device according to claim 1, wherein said low-resistivity conductive layer is formed of either silicide layer, a double layer structure of a polysilicon layer and a silicide layer, or a metal layer.

3. A manufacturing method of a semiconductor memory device having a memory cell section and a peripheral circuit section, comprising the steps of:
forming an interlayer insulating film on a semiconductor substrate;
forming an opening in said interlayer insulating film in said memory cell section;
forming a lower electrode for charge storage filling in said opening and having a protrusion that protrudes from said interlayer insulating film;
covering said protrusion of said lower electrode with a thin insulating film;
forming a low-resistivity conductive film on said protrusion of said lower electrode that is covered with said thin insulating film and on said entire interlayer insulating film in said memory cell section and said peripheral circuit section; and
forming an upper electrode for charge storage opposed to said lower electrode from said conductive layer in said memory cell section, and, concurrently forming a signal line from said conductive layer in said peripheral circuit section.

4. The manufacturing method according to claim 3, wherein said low-resistivity conductive layer is formed by either a silicide layer, a double layer structure of a polysilicon layer and a silicide layer, or a metal layer.
